(19) United States
(12) Patent Application Publication
(10) Pub. No.: US 2013/0149551 A1
(43) Pub. Date: Jun. 13, 2013

(54) DIFFUSION COATING METHOD AND CHROMIUM COAT PRODUCED THEREWITH

(71) Applicant: MTU Aero Engines GmbH, Munich (DE)

(72) Inventors: Markus NIEDERMEIER, Munich (DE); Horst PILLHOEFER, Roehrmoos (DE); Siegfried SEUSS, Muenchen (DE); Stefan MUELLER, Muenchen (DE)

(21) Appl. No.: 13/712,620

(22) Filed: Dec. 12, 2012

Related U.S. Application Data
(60) Provisional application No. 61/673,133, filed on Jul. 18, 2012.

(30) Foreign Application Priority Data
Dec. 12, 2011 (DE) 10 2011 089 131.5

(51) Int. Cl. C23C 16/10; B32B 15/01

(52) U.S. Cl. CPC C23C 16/10; B32B 15/01
USPC 428/666; 427/253; 427/205

(57) ABSTRACT

A method for producing a coating made of metal or a metal alloy on a substrate (1) using a diffusion process is disclosed, in which the substrate undergoes a heat treatment in an atmosphere (4), wherein the atmosphere includes at least one metal halide of the to-be-deposited metal or the metal alloy and wherein, in addition, the substrate is provided at least partially with a layer (2, 3), which includes at least one metal halide in solid and/or liquid form, which preferably has the same constituent parts as the metal halide of the atmosphere. Furthermore, the present invention relates to a chromium coat, which was produced in particular with the method according to the invention and has a chromium proportion of ≧30% by weight in a diffusion zone in the coated substrate.

This application claims the benefit of U.S. Provisional Application No. 61/673,133, filed Jul. 18, 2012, and German Patent Document No. DE 10 2011 089 131.5, filed Dec. 12, 2011, the disclosures of which are expressly incorporated by reference herein.

### BACKGROUND AND SUMMARY OF THE INVENTION

The present invention relates to a method for producing a coating of a metal or a metal alloy on a substrate via a diffusion process, in which the substrate undergoes a heat treatment in an atmosphere, wherein the atmosphere includes at least one metal halide of the to-be-deposited metal or the metal alloy. In addition, the present invention relates to a chromium coat, which is produced in particular with the method according to the invention and has a diffusion zone in the substrate as well as a build-up zone on the substrate.

Diffusion coats for the chromium and zinc enrichment of steel, such as chromalizing for example, or the application of aluminum and chromium-aluminum-rich diffusion coatings (aluminizing, chromatizing, etc.) are known from the prior art. The disadvantage of these diffusion coats, however, is that they tend towards brittleness and thermal fatigue cracks arise. In addition, there are also problems in that the to-be-applied metal such as, e.g., chromium, diffuses in the substrate in too low a concentration so that it does not possess the anti-corrosive properties thereof in an adequate manner. Furthermore, another problem is that when producing diffusion coats in which the substrate is arranged in a powder bed, there is a high incidence of waste from excess powder.

Examples of methods for producing chromium diffusion coats are disclosed in U.S. Pat. Nos. 3,312,546 and 3,623,901. In the case of the methods published there, the to-be-coated substrates are coated with a powder containing chromium, wherein a gas containing halogen is added to the atmosphere during the aging process. In doing so, a multi-sided coating of steel with a glossy surface is supposed to be produced on steel products on the one hand and an adherent, protective chromium coat on the other hand.

Although various methods are already known in the prior art for producing diffusion coats and in particular chromium diffusion coats, there is a further need for optimization to the effect that, on the one hand, a strong enrichment of the to-be-deposited metal or metal alloy is achieved in the region of the diffusion coating and, on the other hand, such a coat has adequate ductility to satisfy requirements for use. In addition, the method is supposed to be environmentally friendly.

The method according to the invention is characterized in that, contrary to the prior art in which a metal halide is provided to produce diffusion coats either in a powdery starting agent or in a gas atmosphere, a combination of gaseous metal halides and solid and/or liquid metal halides are used.

Accordingly, in the case of the method according to the invention, the diffusion process is carried out for coating a substrate with a metal or a metal alloy in an atmosphere, which includes at least one metal halide of the to-be-deposited metal or the metal alloy, wherein, however, in addition, the substrate is provided at least partially with a layer which includes at least one metal halide in a solid and/or liquid form also with at least one metal halide of the to-be-deposited metal or the metal alloy, preferably a metal halide with the same constituent parts as the metal halide of the surrounding atmosphere. The metal halides used may differ for example by different oxidation states in order at the same time to make available gaseous and solid or liquid metal halides with the same constituent parts. In addition, several metal halides such as, for example, aluminum and chromium halides may also be used to deposit an AlCr alloy.

It is possible with the method according to the invention to increase the proportion of the to-be-deposited metal in the diffusion zone of the produced diffusion coat, i.e., in the area of the coat that is produced, which extends into the substrate, so that a higher proportion of the to-be-deposited metal is yielded in the diffusion zone. Correspondingly, effective depositing of the to-be-deposited metal also makes it possible to reduce the quantity of the material to be provided for the diffusion process and therefore the quantity of waste that is incurred during the process. In addition, the build-up zone of the diffusion coat, which is deposited on top of the original surface of the substrate, has a high porosity so that the coat has a good ductility overall.

The metal halide may be arranged on the substrate in liquid or solid form. A liquid metal halide may be deposited on the substrate in form of a film by painting, immersion, spraying and the like.

A solid metal halide may be applied to the substrate in powder form, wherein the powder may have metal halide powder particles with average or maximum particles sizes in the range of 2 μm to 100 μm, in particular 5 μm to 50 μm. The solid metal halide in powder form may be deposited directly on the surface of the substrate or on a film with liquid metal halide.

The powdery metal halide may be applied to the substrate together with other metal particles of the to-be-deposited metal or the metal alloy and/or with inert particles, so-called neutral filling material such as, for example, aluminum oxide or the like.

The metal particles or inert particles, which are applied to the substrate together with the metal halide particles, may have an average or maximum grain size in the range of 5 μm to 4 mm, in particular 10 μm to 400

When applying metal halide particles and metal particles, these may be mixed in a ratio of one to one or the proportion of metal halide particles in the powder mixture may be selected to be in the range of 0.2 to 50% by volume, preferably 0.2 to 10% by volume.

The layer made of liquid metal halide and/or powdery metal halide is configured such that the components of the applied layer essentially retain their states of aggregation under the conditions of the heat treatment without taking the occurring reactions into consideration.

The atmosphere containing metal halides includes an inert gas along with the metal halide, wherein the inert gas may be argon for example. The inert gas may have a partial pressure of 20 mbar to 1050 mbar, while the metal halide may have a partial pressure of 5 mbar to 800 mbar. The atmosphere may be produced in such a way that corresponding halides are vaporized by means of suitable vaporizers, or mixtures of metals and halides with higher oxidation states are produced, which generate gaseous metal halides at high temperatures, wherein the corresponding metal halide vapor is introduced into the atmosphere around the substrate.

The heat treatment of the substrate may be executed at a temperature in the range of 800° C. to 1200° C., in particular 900° C. to 1150° C., and for a duration of 0.5 to 24 hours.

The layer with liquid and/or solid metal halide may be applied to the substrate with a thickness of 0.05 to 20 mm, in particular 0.2 to 10 mm, wherein it is also possible to have only a locally limited application to the substrate, and namely in the areas in which an especially great deposition of the corresponding metal or the metal alloy is desired.

Chromium, aluminum, hafnium, zirconium and/or yttrium may be considered as metals that may be deposited.

A corresponding diffusion coat, which is produced with the method according to the invention, is characterized in particular in that the proportion of the deposited metal in the diffusion zone is ≧30% by weight, in particular ≧50% by weight or up to 80% by weight. Moreover, the build-up coat of the corresponding diffusion coat has a high porosity in the range of 0.2 to 40% by volume resulting in a good ductility of the diffusion coat.

In particular the method according to the invention may be used to deposit a chromium coat on a nickel-based material, especially a nickel-based alloy for building aircraft engines, wherein the proportion of the α-chromium in the diffusion zone is ≧50% of the entire chromium content.

The attached drawings show the following in a purely schematic manner:

### BRIEF DESCRIPTION OF THE DRAWINGS

FIG. 1 is a sectional view through the edge area of a to-be-coated substrate with the adjacent atmosphere during coating; and

FIG. 2 is a partial cross-sectional view of the edge area of the substrate after the coating has been applied.

### DETAILED DESCRIPTION OF THE DRAWINGS

Additional advantages, characteristics and features of the present invention will be made clear by the following detailed description of an exemplary embodiment, wherein the invention is not limited to this exemplary embodiment.

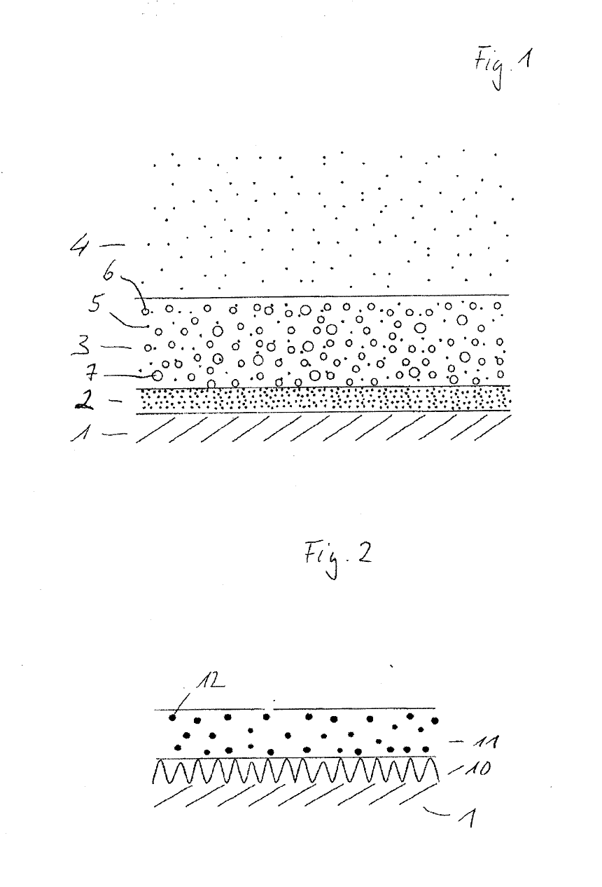

FIG. 1 shows the cross section through the edge area of a to-be-coated substrate as well as the adjacent surroundings during coating.

The substrate 1 is provided with a film 2, which includes a metal halide, and namely CrCl₂ in the present exemplary embodiment. CrCl₂ has chromium as the metal constituent, because a chromium coat is supposed to be formed as a coating on the substrate 1. The substrate 1 may be formed for example by a nickel-based alloy such as those used in engine building.

A powder coat, which also includes a metal halide, is provided on top of the film 2 with the CrCl₂, wherein in the present case the metal component of the halide is again chromium. However, this is a powdery chromium halide with a higher oxidation state in this case, namely CrCl₃ for example. The CrCl₃ has a grain size of less than or equal to 5 μm. In addition to the CrCl₃ particles, metal particles 6 are provided in the powder coat 3, and namely chromium particles again in the present case. The chromium particles have a grain size of approx. 40 μm. The proportion of the chromium particles to the CrCl₃ particles may be selected such that the ratio between the chromium particles 6 and CrCl₃ particles 5 is one to one as related to the volume. However, percentages of 0.2 to 50% by volume, preferably 0.2 to 10% by volume, of the CrCl₃ are also possible.

The powder coat 2 and/or 3 may also have a binding agent.

In addition, it is also possible to provide larger metal particles or inert particles 7 in the powder coat 3 that have average or maximum grain sizes in the range of 5 μm to 4 mm, which guarantee an open-celled structure for the powder coat and make an adequate gas exchange possible.

The surrounding atmosphere 4 is selected in such a way that the atmosphere 4 also includes a metal halide of the to-be-deposited metal, i.e., a chromium halide in the present case. In the present case of chromium deposition on a nickel-based material, the metal halide may be present as ClCr or ClCr₂.

In addition to the metal halide, the atmosphere 4 includes an inert gas such as, for example, argon.

The partial pressures of the inert gas and the metal halide may be selected in such a way that the inert gas is present with a pressure in the range of 20 mbar to 1200 mbar, while the metal halide is present with a partial pressure in the range of 5 mbar to 800 mbar.

The coating is carried out at temperatures between 800° C. and 1200° C., for example 1130° C. with an aging time of 0.5 hours to 24 hours.

Because a chromizing of the substrate 1 may also take place along via the corresponding gaseous phase, it is possible to provide the layer of film 2 and powder coat 3 on a merely locally limited basis in areas of the substrate 1 which require an especially high level of chromizing. However, it is also possible of course, to provide the layer of a liquid film 2 and powdery coat 3 on the entire surface of the substrate 1.

The overall thickness of the layer of film 2 and powder coat 3 may be selected to be in the range of 0.1 mm to 20 mm.

In addition, it is also possible to provide either only the powdery layer coat 3 or only the film with the liquid metal halide.

In addition, it is also possible to dispense with the addition of coarse-grained inert particles or corresponding metal particles in the powdery coat 3.

When carrying out a corresponding chromizing, a chromium coat is yielded on the substrate, namely e.g., the nickel-based material as shown in FIG. 2. A diffusion zone 10 forms on the substrate 1, which is directed from the original substrate surface inwardly to the substrate. In addition, configured above the original substrate surface is a build-up zone 11, which includes a plurality of pores 12, the proportion of which in the build-up zone 11 lies in the range of 0.2 to 40% by volume.

The build-up zone 11 is essentially formed of a-chromium enriched with a proportion of 30 to 90% by weight, preferably 40 to 80% by weight. The α-chromium in this case includes approximately 10 to 80% of the entire coat to be formed.

Because of the high porosity in the build-up zone, the build-up zone has a hardness ≦800 HV (Vickers hardness) and the elongation at tear is ≧0.5%. This results in a chromium coat characterized by high ductility along with a high chromium proportion.

Although the present invention was described in detail based on the exemplary embodiment, it is clear to a person skilled in the art that this invention is not limited to this embodiment, but that in fact modifications are possible by omitting individual features or by a different combination of features without leaving the protective scope that is defined by the enclosed claims. In particular, the present invention includes all combinations of all individual features presented.

What is claimed is:

1. A method for producing a coating (10, 11) made of metal or a metal alloy on a substrate (1) via a diffusion process, in which the substrate undergoes a heat treatment in an atmosphere (4), wherein the atmosphere includes at least one metal halide of the to-be-deposited metal or the metal alloy,
characterized in that
in addition the substrate is provided at least partially with a layer which includes at least one metal halide in solid and/or liquid form.

2. Method according to claim 1,
characterized in that
the substrate (1) is provided with a film (2), which includes a metal halide in liquid form, in particular a metal halide having the same metal or the same components as the metal halide of the surrounding atmosphere.

3. Method according to claim 1,
characterized in that
a powder coat (3) with the solid metal halide, in particular with a metal halide having the same metal as the metal halide of the surrounding atmosphere, is arranged over the film (2) with the liquid metal halide or directly on the substrate (1).

4. Method according to claim 3,
characterized in that
the powder coat (3) with the solid metal halide includes metal particles or inert particles.

5. Method according to claim 3,
characterized in that
the powdery metal halide particles (5) have an average or maximum grain size in the range of 2 μm to 100 μm, in particular in the range of 5 μm to 50 μm and/or the metal particles (6) or inert particles (7) have an average or maximum grain size grain size in the range of 5 μm to 4 mm.

6. Method according to claim 3,
characterized in that
the metal halide particles (5) are provided with a proportion of 0.2% by weight to 50% by weight, in particular 2% by weight to 10% by weight in the powder coat 3, or the metal halide particles (5) and the metal particles (6) are provided in a ratio of 1 to 1.

7. Method according to claim 1,
characterized in that
the components of the applied layer (2, 3) retain their states of aggregation under the conditions of the heat treatment without taking reactions into consideration.

8. Method according to claim 1,
characterized in that
the atmosphere (4) includes an inert gas, which in particular has a partial pressure of 20 mbar to 1200 mbar.

9. Method according to claim 1,
characterized in that
the metal halide is present in the atmosphere (4) with a partial pressure of 5 mbar to 800 mbar.

10. Method according to claim 1,
characterized in that
the heat treatment is carried out at 800° C. to 1200° C., in particular 900° C. to 1150° C., for a time duration of 0.5 to 24 hours.

11. Method according to claim 1,
characterized in that
the layer (2, 3) is provided on the substrate (1) on an only locally limited basis.

12. Method according to claim 1,
characterized in that
the layer (2, 3) has a thickness of 0.1 mm to 20 mm.

13. Method according to claim 1,
characterized in that
Cr, Al, Hf, Zr and/or Y are used as metals.

14. A chromium coat on a metallic substrate (1), in particular produced according to the method according to one of preceding claims, with a diffusion zone (10) in the substrate and a build-up zone (11) on the substrate,
characterized in that
the build-up zone (11) has a chromium proportion of greater than or equal to 30% by weight.

15. Chromium coat according to claim 14,
characterized in that
the α-Cr in the build-up zone (11) has a proportion of greater than or equal to 50% by weight of the chromium content.

16. Chromium coat according to claim 14,
characterized in that
the build-up zone (11) has a porosity of 0.2 to 40% by volume.
